(19) United States
(12) Patent Application Publication
(10) Pub. No.: US 2011/0285406 A1
(43) Pub. Date: Nov. 24, 2011

(54) INDUCTIVE SENSOR AND METHOD OF ASSEMBLY

(76) Inventors: Burkhard REETMEYER, Konstanz (DE); Thomas Röhm, Konstanz (DE); Pietrino Pirisinu, Wiesendangen (CH)

(21) Appl. No.: 13/111,223

(22) Filed: May 19, 2011

(30) Foreign Application Priority Data
May 21, 2010 (DE) DE102010021189.3

(51) Int. Cl. G01R 27/28; H05K 3/34

(52) U.S. Cl. 324/654; 29/840

(57) ABSTRACT

A sensor includes a coil arranged in a housing. The coil is electrically connected to a printed circuit board, which is likewise arranged in the housing. Sensor terminals are arranged at the printed circuit board on a side of the housing opposite the coil. The coil has at least two contacts running asymmetrically to a coil axis, which are connected to the printed circuit board. A method of assembling the sensor is also provided.

### CROSS REFERENCE TO RELATED APPLICATIONS

This application claims the benefit of priority under 35 U.S.C. §119 of German Patent Application DE 102010021189.3 filed May 21, 2010, the entire contents of which are incorporated herein by reference.

### FIELD OF THE INVENTION

The present invention pertains to an inductive sensor, and especially a proximity sensor, as well as a method/process for the assembly thereof.

### BACKGROUND OF THE INVENTION

Inductive sensors are well known. These are sensors, which comprise a coil, which is usually wound around a ferrite core and which is used to form an oscillator.

Besides the oscillator, such a proximity sensor usually comprises a printed circuit board, which is equipped with integrated circuits, which comprise, for example, an electronic analyzing unit and an amplifier.

When a metallic object approaches the sensor, the oscillator is detuned, and thus, a signal reflecting the approaching object can be generated.

All components of the sensor are for the most part integrated in a housing, wherein typically the coil is arranged on the front surface of the sensor. Typically the printed circuit board with the electronic components is located behind the coil. On the back side, i.e., the side opposite the coil, terminal contacts are provided, which form an interface to control the sensor and to analyze the signals thereof.

Proximity sensors of this type are usually hermetically sealed. The mounting of prior-art sensors is complicated. Thus, the printed circuit board has to be electrically connected to the contacts of the coil as well as to the terminal contacts for connecting the sensor. Because of the integration into a sensor housing, which usually has a cylindrical design, it is for the most part not possible to place all the above-mentioned contacts on one side of the printed circuit board in order to be able to thus solder them from one side.

To simplify assembly, WO2007/131374 suggests using clamp contacts instead of a soldered connection.

The assembly of the sensor housing and the fastening of the coil or of the coil housing usually take place by means of an adhesive bonded joint. Such bonded connections have the drawback that waiting times arise because of the necessary curing times of the adhesive during the mounting. Furthermore, the components to be bonded have tolerances. This may lead to fluctuations in quality of the individual sensors, since in some cases the individual components are not positioned as desired and are thus tuned to one another.

### SUMMARY OF THE INVENTION

A basic object of the present invention is to provide an inductive sensor, in which the mounting effort is reduced. Another object of the present invention is to reduce mounting-related fluctuations in quality.

According to the present invention, a sensor is provided, which comprises a coil structure (coil arrangement) arranged in a housing. The coil structure includes a coil electrically connected to a printed circuit board, which is likewise arranged in the housing. Contacts for the connection of the sensor are arranged on the printed circuit board on a side of the housing opposite the coil structure. The coil structure has at least two contacts running (extending) asymmetrically to a coil axis, which are connected to the printed circuit board.

The printed circuit board is equipped with electronic components, for example, with integrated circuits, which are used for the analysis and/or amplification of the sensor signals. Such a sensor is usually active in the direction of a coil axis. The turns of the coil usually run at right angles to the printed circuit board.

Contacts for the connection of the sensor, which are electrically connected to the printed circuit board, are arranged on the opposite side of the housing. These contacts may be part of a plug, or, as is provided in an alternative embodiment, part of a cable, which is guided from the sensor housing and is used for the connection of the sensor.

It is understood that both a flexible and a rigid printed circuit board may be used as a printed circuit board. According to the present invention, the coil structure has at least two contacts running asymmetrically to a coil axis, which are connected to the printed circuit board.

The coil axis is defined in that it runs in the center of the coil at right angles through a plane, which is formed by the turns of the coil.

Further, the coil structure has two contacts, which, in conventional coils, are usually arranged symmetrically opposite the coil axis and therefore lie exactly opposite one another.

By contrast, according to the present invention, the coil contacts do not lie opposite one another, but rather are arranged asymmetrically. The centers of the contacts towards the coil axis preferably form an angle between 60° and 170°, especially preferably between 110° and 120°.

In this way, it is possible to arrange both contacts of the coil structure on one side of a printed circuit board arranged exactly in the center of the housing.

As a result, for example, both the coil contacts and terminal contacts of the sensor can be soldered with the printed circuit board from one side, which makes mounting considerably easier.

In a variant of the present invention, the coil structure includes a coil that is wound onto a coil body, which has contacts running asymmetrically to the coil axis.

In contrast to the use of air core coils (in combination with a shell core), the use of a coil body makes possible the embodiment of a more true-to-size component.

In a variant of the present invention, the coil body has a ring-shaped design with a central cutout. This cutout has internal clamping webs in an embodiment of the present invention. These clamping webs may be used, for example, for fastening to a shell core, which forms a housing of the coil.

In this case, the shell core may have ducts for leading through the asymmetrically running contacts. The shell core is arranged at one end of the housing and may be positioned exactly.

In a preferred embodiment of the present invention, the shell core is fastened in a positive locking and/or non positive locking manner. Thus, the use of adhesives can be omitted in the mounting with the waiting times involved therewith.

It is especially provided that the printed circuit board itself has wings acting as spring elements, which involve at least one clamping connection with the shell core. The wings mesh with a central cutout of the shell core. At the same time, the shell core lies against support surfaces, arranged on the front side, of the printed circuit board. The shell core is centered by means of the wings, and an exact position of the shell core at right angles to the printed circuit board is guaranteed by the support surface. At the same time, the shell core is designed as a coil housing in this embodiment. However, a separate coil housing may also be provided. Thus, the shell core can be mounted in an especially simple manner. The shell core of the coil structure is thus connected in a positive locking and/or non positive locking manner to the printed circuit board. The wings are preferably part of the printed circuit board, thus are not springs fastened to the element, but rather consist of the same materials as the printed circuit board itself. Thus, a clamping connection can be prepared in a very simple way, which, moreover, is very true to size. In this embodiment according to the present invention, an inductive sensor can be mounted with high accuracy in a very simple manner.

The shell core has ducts running asymmetrically to an axis of rotation for leading through the contacts. The axis of rotation is defined as an axis, which is designed as rotationally symmetrical to the jacket surface of the shell core.

In contrast to commercially available shell cores, the jacket surface of the shell core is closed in a preferred embodiment of the present invention, and the contacts are guided through the bottom of the shell core. Losses are reduced due to the absence of lateral openings, and in this advantageous embodiment, an improved performance of the sensor is achieved.

In a preferred embodiment of the present invention, the printed circuit board is fastened in a positive locking and/or non positive locking manner in the housing.

Thus, likewise no adhesive has to be used for fastening the printed circuit board, which makes the mounting of the sensor easier. In conjunction with a positive and/or non positive locking connection of the printed circuit board to a coil housing, the entire sensor may thus be joined together in a very simple way without adhesive and even without using a tool. In this case, the printed circuit board can at first be connected to a coil housing, especially a coil body, in a positive and/or non positive locking manner. Preferably, a coil body is likewise connected to the coil housing in a positive and/or non positive locking manner. The components are thus aligned with one another exactly, and the contacts of the coil structure may then be soldered to the printed circuit board. Accordingly, in a variant of the present invention, provisions are made that the coil and shell core are mechanically held and fastened at the printed circuit board by means of two soldered joints, wherein at the same time the coil is electrically contacted by means of the two soldered joints.

It is understood that, nevertheless, in the sense of the present invention provisions may also be made to fill up the sensor housing with a sealing compound. This sealing compound is primarily used for improved protection against moisture.

In a variant of the present invention, the printed circuit board has lateral contact elements. Via these contact elements, which lie against the inner wall of the housing, the inner housing can be electrically connected to a protective wiring on the printed circuit board. For this, the housing consists of metal or is provided with a metallic layer or with a metallic insert. By this design, a sensor with improved electromagnetic compatibility (EMC) is provided.

In a variant of the present invention, the contact elements are designed for fitting and/or guiding the printed circuit board in the housing. Thus, the contact elements assume, besides the contacting for the shielding of the housing, the task of positioning the printed circuit board exactly in the housing.

In a preferred embodiment, both the contacts of the coil structure and the terminal contacts for the connection of the sensor can be soldered on a same surface (same side) of the printed circuit board. Thus, an otherwise expensive soldering method can be omitted. Furthermore, manual soldering is no longer absolutely necessary.

Rather, the connection of the printed circuit board to terminal contacts as well as to the coil can be performed in an automated manner in a single work step. However, a manual soldered connection is also considerably simplified.

The sensor or sensor housing has preferably an essentially circular cylindrical design, wherein it is understood that typically such a sensor still comprises grip surfaces, a threaded section for mounting a plug, etc., without hereby deviating from the circular cylindrical design in the sense of the present invention.

In a preferred embodiment of the present invention, the coil structure comprises coil turns wound about a coil body, wherein the coil body comprises injection-molded contact pins and has a temperature resistance of at least 130° C. Thus, the coil body can be soldered to the printed circuit board, without there being the risk of the coil body being damaged during the soldering.

Among other things, a high-temperature-resistance liquid crystal polymer (LCP) is suitable.

The relatively fine turns of the coil may thereby be wound about the contact pins of the coil and be subsequently soldered.

The turns of the coil run essentially at right angles to the printed circuit board, i.e., a plane, which lies along a turn of the coil, is arranged at right angles to the printed circuit board.

The printed circuit board itself lies essentially along an axis of rotation of the housing, wherein an axis of rotation is defined as an axis of symmetry of the jacket surface of the housing, which has preferably a circular cylindrical design.

The present invention pertains, furthermore, to a method for mounting an above-described sensor, especially an inductive sensor. A coil with asymmetrically designed contacts as well as contact pins for contacting the sensor is soldered to a surface of a printed circuit board. The coil is inserted into a shell core, wherein the shell core is connected to the printed circuit board in a positive locking and/or non positive locking manner.

Due to the present invention, adhesive bonded joint connections may be omitted, which considerably simplifies the mounting of the sensor.

The printed circuit board is preferably inserted along an axis of rotation of the housing and can thus occupy the maximum possible width in the housing. At the same time, the printed circuit board may thus be held in a positive locking manner in an inner housing, which has a circular cylindrical design, without additional guides. In a variant of the present invention, the printed circuit board is guided by means of lateral contact elements and is thus arranged in the housing with an accurate fit.

In a preferred embodiment of the present invention, the coil comprises a coil body made of plastic, especially a coil body made of a liquid crystal polymer. This coil body is clamped onto a shell core, which likewise makes mounting easier.

In another embodiment of the present invention, the printed circuit board is provided, on the sensor side, with support surfaces with a flat design, which are used for the rectangular contact of a coil housing, especially of the above-described shell core. For this, the printed circuit board is preferably provided on its front side with surfaces milled true to size. Consequently, the coil housing can be positioned exactly to the printed circuit board, as a result of which it is guaranteed that the coil axis very accurately agrees with the intended direction of action of the sensor.

The present invention is explained in detail with reference to the attached drawings, in which identical reference numbers designate identical structures. The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

In the drawings:

FIG. 1 is a perspective view of a sensor with cut-open housing;

FIG. 2 is a sectional view of the sensor, wherein the sectional plane runs at right angles to the printed circuit board and along an axis of rotation of the housing;

FIG. 3 is a perspective view of the components arranged in the housing of the sensor;

FIG. 4 is a detailed perspective view of the coil body;

FIG. 5 is a perspective view of a shell core, which is used for mounting the coil body;

FIG. 6 is another perspective view of the shell core from a different perspective;

FIG. 6a is a sectional view of the shell core shown in FIGS. 5 and 6;

FIG. 7 is a top view of the printed circuit board;

FIG. 8 is a sectional view of the sensor in the top view of the printed circuit board;

FIG. 9 is a sectional view of the sensor, at right angles to the printed circuit board;

FIG. 10 is a detailed view of the coil housing fastened to the printed circuit board; and

FIG. 11 is another detailed view of the coil housing fastened to the printed circuit board.

### DESCRIPTION OF THE PREFERRED EMBODIMENTS

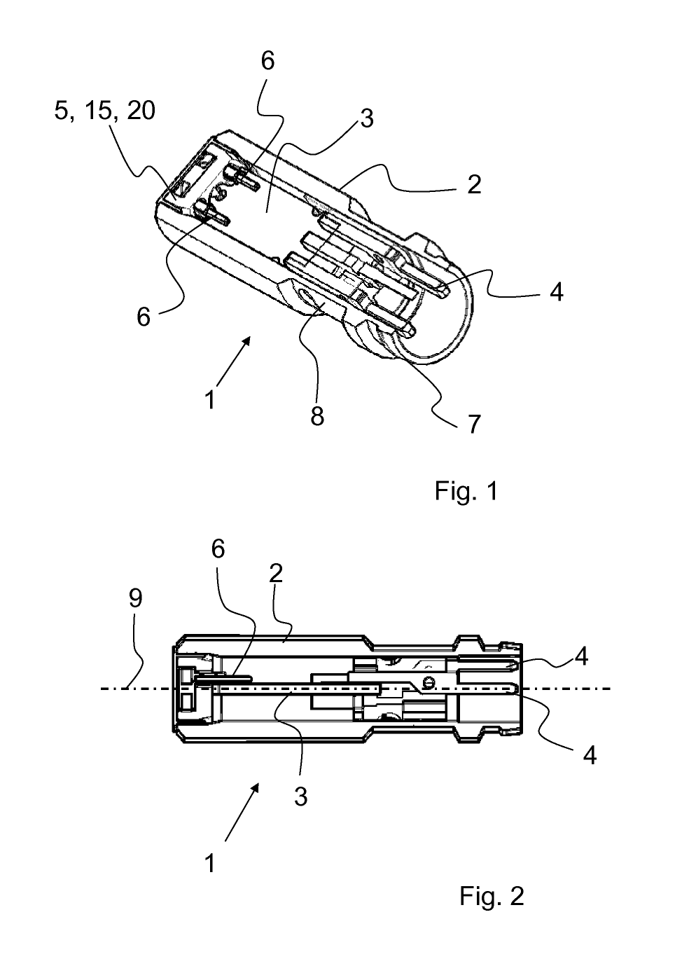

Referring to the drawings in particular, referring to FIG. 1, the essential elements of an inductive sensor 1 shall be shown. A perspective view, in which the upper part of the housing 2 is removed, can be seen. The sensor 1 comprises a housing 2, in which a printed circuit board 3 is arranged. The housing 2 has an essentially circular cylindrical shape. A coil 5 is located on the front side of the housing.

A sensor terminal 4 is arranged on a side of the sensor 1 opposite the coil 5. Both the sensor terminal 4 and contacts 6 of the coil 5 are electrically connected to the printed circuit board 3. The printed circuit board 3 has other electronic components such as integrated circuits, which are used for analyzing and amplifying the sensor signals (not shown).

Furthermore, the housing has a grip surface 8 as well as a collar 7. The collar 7 may be designed as a threaded section as well and is used for connecting a plug (not shown). It can already be seen in this view that both the sensor terminal 4 and all the contacts 6 of the coil 5 are arranged on one side of the printed circuit board 3. Thus, a mounting method of the sensor 1 is made considerably easier.

How exactly this embodiment is possible is explained by referring to other drawings.

FIG. 2 shows a sectional view of an axis of rotation 9 of the coil housing and along a plane running at right angles to the printed circuit board 3. It can be seen in this view that the contacts 6 of the coil 5 and the sensor terminal 4, at least insofar as these border on the printed circuit board 3, lie above the printed circuit board 3.

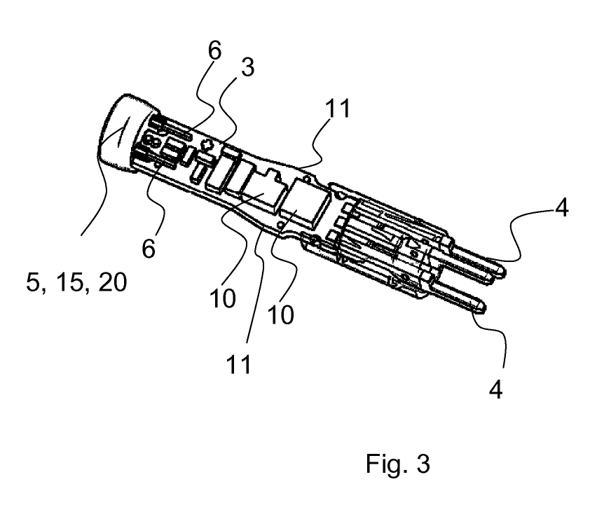

The structure of sensor 1 shall be explained in detail with reference to FIG. 3. The sensor 1 consists at least of a coil structure comprising a shell core 20, a coil 5 and coil body 15. The contacts of the coil 5 are electrically connected to the printed circuit board 3. The electrical connection preferably takes place by means of soldering. With this soldering, the coil 5 and shell core 20 are mechanically held and fastened to the printed circuit board 3 by means of two soldered joints, wherein at the same time the coil 5 is electrically contacted by means of the two soldered joints.

The printed circuit board 3 has an essentially rectangular, long-drawn shape and has integrated circuits 10, which are used, for example, to amplify and analyze the sensor signals.

The additional mechanical connection between coil 5 and printed circuit board 3 shall be explained below with reference to other drawings.

Furthermore, the printed circuit board 3 has lateral contact elements 11, in which the width of the printed circuit board 3 is enlarged.

These contact elements 11 are used for an electrical connection to the inner wall of the sensor housing 2 and at the same time are used for fitting or guiding printed circuit board 3 in the sensor housing 2. The contact elements 11 may be electrically connected to the housing 2 of the sensor 1 via a condenser (not shown). On the back side, the sensor terminal 4 is soldered to the printed circuit board 3.

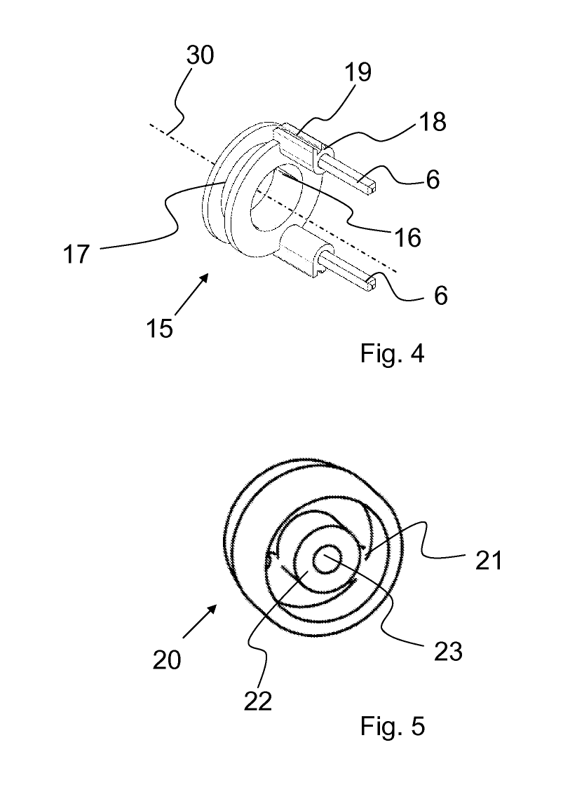

The details of the design of the coil structure with coil 5 shall be explained in detail with reference to the figures (see FIG. 4 through FIG. 6). FIG. 4 shows the coil body 15, which comprises a groove 17, onto which the individual fine turns of the coil 5 (not shown) are wound. Furthermore, the coil body 15 has the contacts 6 for connecting the coil. These contacts run essentially in the direction of the coil axis 30.

Guide grooves 19, into which the two ends of the coil wire (not shown) can be inserted or clamped in, are provided between the contacts 6 and groove 17, in which the turns of the coil 5 (not shown) run. The coil wire can be wound about the contacts 6 and soldered there.

The coil body 15, with the exception of contacts 6, consists of a high-temperature-resistant plastic, and especially of a liquid crystal polymer, which can be connected to the contacts 6 in the injection molding method. Knurled contact pins, from which the wire of the coil 5 (not shown) can be wound up more easily and can be soldered in a fixed manner, are preferably used as contacts 6.

The coil body 15 has a ring-shaped design and has clamping webs 16 on its inner jacket surface, which are used for the fastening thereof.

Three clamping webs 16, which are offset to one another at an angle of 120° each, are provided in this exemplary embodiment.

FIG. 5 shows a shell core 20, which is used for receiving the coil body 15 shown in FIG. 4 and thus forms the actual housing of the coil 5. The shell core 20, which can be made of ferrite, has an essentially circular cylindrical design and comprises a recess 21, which is used for receiving the coil body 15 (see FIG. 4).

A cylinder 22, which is arranged axially in relation to the recess 21 and which may also be slightly conically beveled, is provided for fastening the coil body 15. The coil body 15 is clamped onto this cylinder 22. The use of an adhesive may thus be omitted.

The cylinder 22 has a central hole 23, whose function is explained in detail in the following drawings.

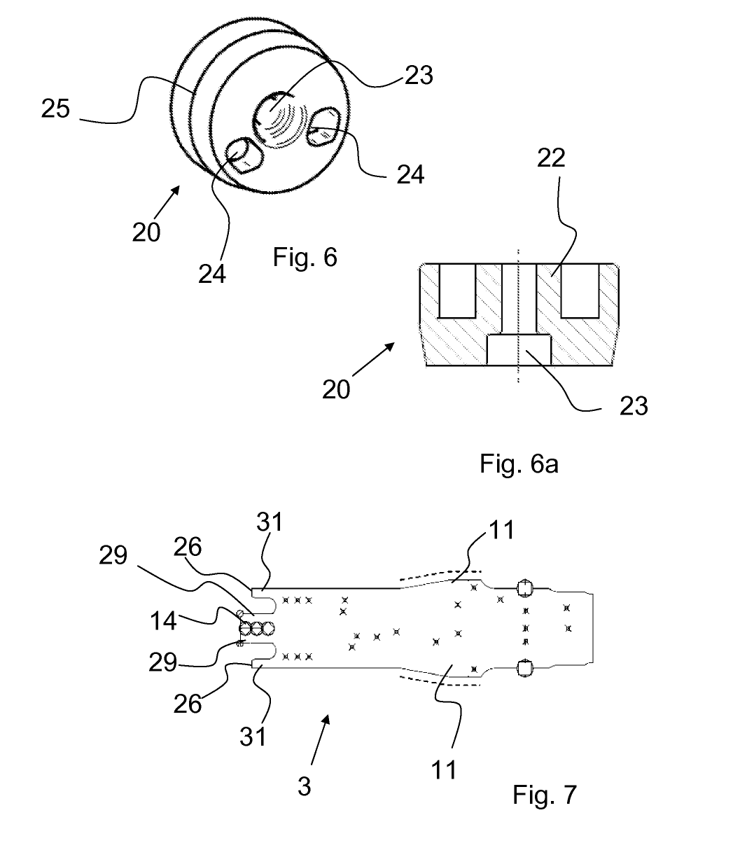

FIG. 6 shows another perspective view of the shell core 20. Central hole 23 can be seen. The term “hole” is used only for geometric definition in the sense of the present invention. An essentially circular cylindrical cutout is defined here.

Furthermore, the shell core 20 has two asymmetrically arranged ducts 24, which form an angle from preferably 80° to 150°, especially preferably 110° to 120°, in this exemplary embodiment.

The jacket surface 25 of the shell core 20 may, as shown in this exemplary embodiment, likewise be slightly beveled at least in some sections.

FIG. 6a shows a sectional view of the shell core 20 along a plane lying on its central axis. The hole 23 has two different diameters, wherein the larger diameter is used for clamping the printed circuit board 3, as still shown in detail below. The opposite cylinder 22 is used for clamping the coil body 15 (see FIG. 4). It is understood that both the inner surface of the hole 23 and the outer surface of the cylinder 22 may still have webs or the like in order to improve the clamping action by means of a simultaneous positive-locking connection.

FIG. 7 shows a schematic top view of the printed circuit board 3. The printed circuit board 3 has an essentially rectangular design, but has lateral contact elements 11, which protrude from this rectangular shape.

As already shown, the contact elements 11 are used for contacting the inner wall of the housing 2 as well as fitting or guiding means.

On the sensor side, the printed circuit board 3 is provided with support surfaces 26 running at right angles to the paper plane in this view. These support surfaces 26 are designed at right angles to and true to size at the edges of the printed circuit board 3. The printed circuit board 3 has protruding webs 31 for this purpose.

Another web which is provided with a recess 14 is located between the webs 31. As a result of this, the other web is divided into two wings 29, which act as spring elements and with which the shell core 20 can be clamped onto the printed circuit board 3 with its central hole 23 (see FIG. 6a). To provide an additional positive-locking connection, the wings 29 may have lateral locking means (not shown). The front surface of the wings 29 protrudes out via the support surfaces 26 in order to clamp the cylindrical coil housing, designed as a shell core 20, with a central cutout onto the printed circuit board 3, wherein the shell core 20 comes to lie on the support surfaces 26.

In this exemplary embodiment, the recess 14 is formed by three partly overlapping holes. Other notches, for example, a straight notch are conceivable as well.

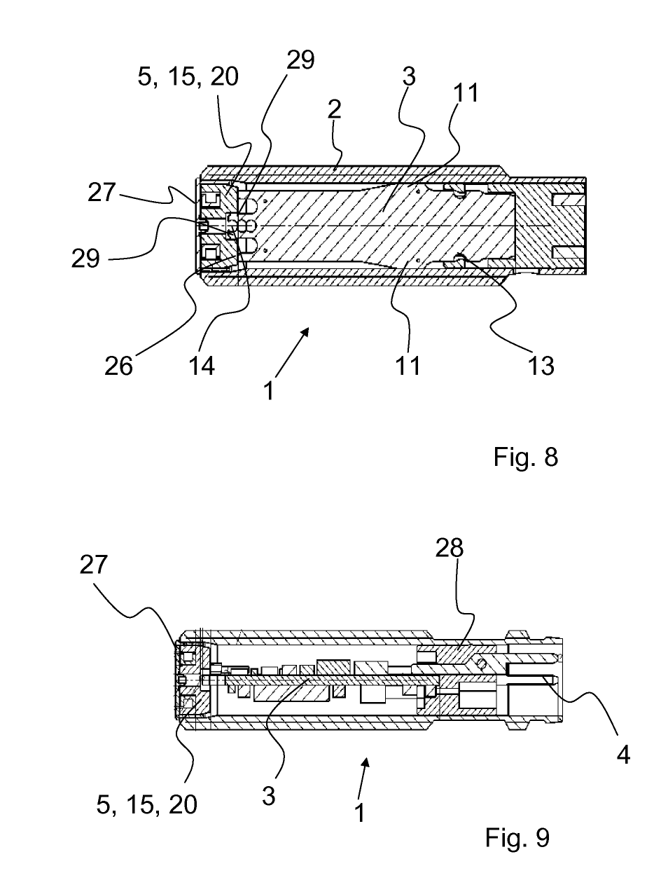

FIG. 8 shows a sectional view of the sensor 1, wherein the section here is parallel to the surface along the printed circuit board 3. The printed circuit board 3 comprises laterally arranged cutouts 13. During the mounting, the printed circuit board 3 is pushed into the housing 2. For exact positioning, the printed circuit board has lateral contact elements 11, with which the inner wall of the housing 2 is contacted at the same time. This housing 2 consists of metal or has a metallic coating or a metallic insert on the inside.

The coil 5 is fastened to the printed circuit board 3, in which the wings 29, as is still shown in detail below, are clamped into the hole of the shell core 20.

So that the shell core 20 is positioned exactly at right angles to the printed circuit board 3, it lies against the support surfaces 26 on the back side.

At the front, the sensor 1 is closed with a front stop element 27, which can be fastened by a press fit or which can be inserted after filling the housing 2 with a sealing compound.

FIG. 9 shows another sectional view of sensor 1 here at right angles to the printed circuit board 3. Printed circuit board 3 as well as coil 5 are arranged between front stop element 27 and rear stop element 28. Sensor 1 is hermetically sealed by means of the stop elements 27 and 28 as well as by means of a sealing compound. It is understood that still other sealing elements may be present for this purpose. The sensor terminal 4, which is connected to the printed circuit board 3, is guided by means of a rear stop element 28.

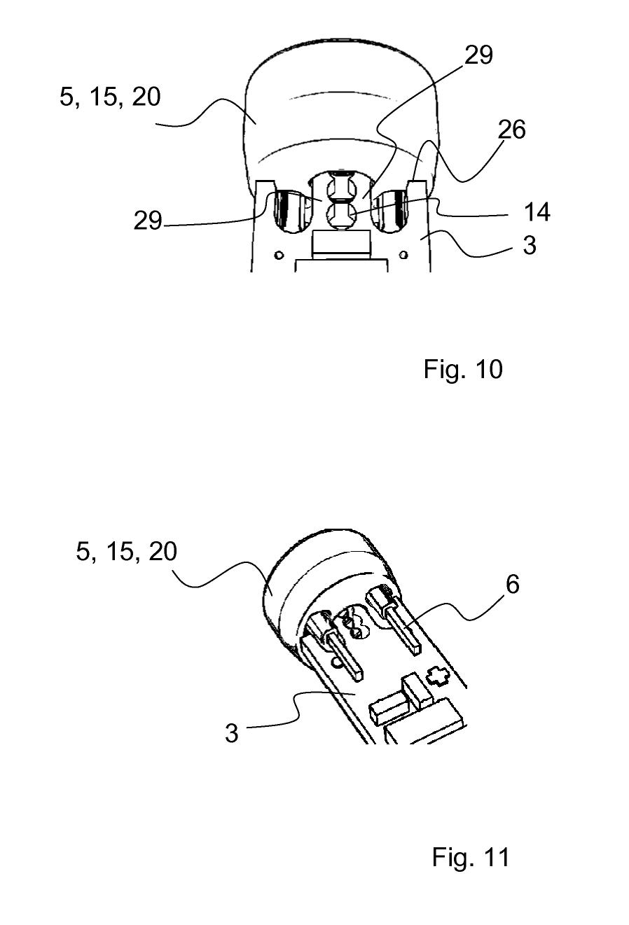

FIG. 10 shows a perspective detailed view of the front part of a sensor 1. The coils 5 with the shell core 20 can be seen. In this exemplary embodiment, the shell core 20 is mechanically connected by means of the wings 29, which wings 29 mesh with the cutout of the shell core 20. The wings 29 are preferably designed as part of the printed circuit board 3.

The shell core 20 lies against support surfaces 26 on the back side. This shell core 20 is positioned very simply true to size to the printed circuit board 3, by means of the simultaneous centering of the shell core 20 because of the clamping onto the wings 29.

FIG. 11 shows another detailed view of the front part of the sensor 1. Especially the contacts 6, which are connected electrically and mechanically to the printed circuit board 3 by soldering, can be seen here.

By means of the present invention, an inductive sensor 1 can be provided, which can be mounted easily, wherein an improved quality is guaranteed in spite of the simplified mounting.

While specific embodiments of the invention have been shown and described in detail to illustrate the application of the principles of the invention, it will be understood that the invention may be embodied otherwise without departing from such principles.

List of Reference Numbers:

| | |
|---|---|
| 1. | Sensor |
| 2. | Housing |
| 3. | Printed circuit board |
| 4. | Sensor terminal |
| 5. | Coil |
| 6. | Contacts |
| 7. | Collar |
| 8. | Grip surfaces |
| 9. | Axis of rotation |
| 10. | Integrated circuit |
| 11. | Contact element |
| 13. | Cutout |
| 14. | Recess |
| 15. | Coil body |
| 16. | Clamping web |
| 17. | Groove |
| 19. | Guide groove |
| 20. | Shell core |
| 21. | Recess |
| 22. | Cylinder |
| 23. | Hole |
| 24. | Leadthrough |
| 25. | Jacket surface |
| 26. | Support surface |
| 27. | Front stop element |
| 28. | Rear stop element |
| 29. | Wing |
| 30. | Coil axis |
| 31. | Web |

What is claimed is:

1. A sensor comprising:
a housing;
a printed circuit board arranged in the housing;
a coil structure arranged in the housing, the coil structure being electrically connected to the printed circuit board;
a sensor terminal provided at the printed circuit board on a side of the housing opposite to the coil structure, wherein the coil structure has at least two contacts running asymmetrically to a coil axis, each of the at least two contacts being connected to the printed circuit board.

2. A sensor in accordance with claim 1, wherein the housing has an essentially cylindrical design and the printed circuit board is essentially arranged centrally in the cylindrical housing.

3. A sensor in accordance with claim 1, wherein the coil structure includes a coil and a coil body wherein the coil is wound on the coil body, and the coil body comprises the contacts running asymmetrically to the coil axis.

4. A sensor in accordance with claim 3, wherein the coil body has a ring-shaped design and has internal clamping webs.

5. A sensor in accordance with claim 3, wherein the coil body is arranged in a shell core, wherein the shell core has ducts for leading through the asymmetrically running contacts.

6. A sensor in accordance with claim 5, wherein:
the shell core is arranged at an end of the housing and is fastened in at least one of a non positive manner and positive locking manner to the housing; and
a jacket surface of the shell core is closed.

7. A sensor in accordance with claim 5, wherein the coil and the shell core are held mechanically and are fastened at the printed circuit board by means of two soldered joints, wherein the coil is electrically in contact with the printed circuit by both of the two soldered joints.

8. A sensor in accordance with claim 5, wherein the printed circuit board has wings forming springs to which the shell core is fastened.

9. A sensor in accordance with claim 1, wherein:
the printed circuit board is connected in at least one of a positive locking manner and non positive locking manner to the housing;
the printed circuit board has lateral contact elements; and
the contact elements at least one of fit and guide the printed circuit board in the housing.

10. A sensor in accordance with claim 1, wherein the contacts of the coil structure and contacts of the sensor terminal are soldered to a same surface of the printed circuit board.

11. A sensor in accordance with claim 1, wherein the coil structure comprises a coil with turns wound about a coil body, wherein the coil body comprises injection-molded contact pins.

12. A sensor in accordance with claim 5, wherein the printed circuit board has front-side support surfaces, against which the shell core lies.

13. A method for assembling a sensor, the method comprising the steps of:
providing a housing;
providing a printed circuit board;
providing a coil structure having at least two contacts running asymmetrically to a coil axis,
providing a sensor terminal at the printed circuit board;
soldering the contacts running asymmetrically to the coil axis onto a surface of the printed circuit board;
inserting the circuit board and the coil structure in the housing.

14. A method according to claim 13, wherein the coil structure includes a coil inserted into a shell core, wherein the shell core is connected in at least one of a positive manner and a non positive locking manner to the printed circuit board.

15. A method in accordance with claim 14, wherein:
the printed circuit board is inserted along an axis of rotation of the housing, wherein the printed circuit board has lateral contact elements and is guided by the lateral contact elements during the inserting of the circuit board in the housing; and
the printed circuit board is provided with support surfaces having a flat design, the support surfaces being used for a rectangular contact with the coil structure.

16. A method in accordance with claim 14, wherein the coil structure comprises a coil body made of plastic which is clamped onto the shell core.

17. A method in accordance with claim 16, wherein:
the housing has an essentially cylindrical design and the printed circuit board is essentially arranged centrally in the cylindrical housing; and
the coil is wound on the coil body, and the coil body comprises the contacts running asymmetrically to the coil axis.

18. A method in accordance with claim 17, wherein the contacts of the coil structure and contacts of the sensor terminal are soldered to a same surface of the printed circuit board.

19. A method in accordance with claim 14, wherein the coil structure comprises a coil with turns wound about a coil body, wherein the coil body comprises injection-molded contact pins and the at least two contacts running asymmetrically comprise the contact pins.
